(19) United States
(12) Patent Application Publication
(10) Pub. No.: US 2002/0036297 A1
(43) Pub. Date: Mar. 28, 2002

(54) Low absorption sputter protection layer for OLED structure

(76) Inventor: Karl Pichler, Santa Clara, CA (US)

Correspondence Address: COLLIER, SHANNON, SCOTT, PLLC, 3050 K STREET, NW, SUITE 400, WASHINGTON, DC, 20007, US

(21) Appl. No.: 09/775,824

(22) Filed: Feb. 5, 2001

Related U.S. Application Data
(60) Provisional application No. 60/180,280, filed on Feb. 4, 2000.

(30) Foreign Application Priority Data
Feb. 5, 2001 (US) PCT/US01/03720

(51) Int. Cl. H01L 21/00; H01L 33/00; H01J 63/04

(52) U.S. Cl. 257/103; 438/22; 313/506

(57) ABSTRACT

The present invention is directed to an Organic Light Emitting Device (OLED) that provides improved sputter protection of the organics in the OLED, and a method of making the OLED. The top emitting OLED of the present invention has a substrate, an anode layer overlying the substrate, and a stack of one or more layers of light emitting organic material overlying the anode layer. The top emitting OLED of the present invention also has a first cathode layer overlying the stack of light emitting organic material, a second cathode layer overlying the first cathode layer, and a third cathode layer overlying the second cathode layer. The second cathode layer comprises a metal, alloy, or intermetallic of: Zr, Au, or Ta.

### CROSS-REFERENCE TO RELATED APPLICATIONS

This application claims priority to U.S. Provisional Patent Application No. 60/180,280, filed Feb. 4, 2000.

### FIELD OF THE INVENTION

The present invention relates to Organic Light Emitting Devices (OLEDs) that provide improved sputter protection of the organics in the OLED, and methods of making these devices.

### BACKGROUND OF THE INVENTION

Organic light emitting diode devices have been known for approximately two decades. An OLED device is typically a laminate formed on a substrate such as soda-lime glass or silicon. In its simplest form, an OLED comprises a light-emitting layer of one or more luminescent organic solids sandwiched between a cathode and an anode. When a voltage is applied across the device (cathode to anode), the organic solids give off light.

One particular type of OLED device that is especially useful for display applications is uses a so-called up-emitting OLED. By convention, the transparent electrode (conductive layer) through which light is transmitted in an up-emitting OLED is a cathode.

With reference to FIG. 1, a typical up-emitting OLED device 10 includes a substrate 100, a bottom electrode 110 made from an electrically conductive material (e.g. patterned Si), a hole-injection layer (HIL) 120, a stack of one or more layers of light emitting organic material 200 overlying the HIL, an electron injection layer (EIL) 310 and a transparent electrode 320.

This top electrode 320 is a cathode and is made up of a material such as indium tin oxide (ITO)). The cathode is laid on top of the EIL 310 made up of a material such as MgAg or a combination of MgAg and CuPc, and the EIL overlies the organic layers 200. A cathode made up of ITO provides a relatively transparent layer having low sheet resistance. The MgAg HIL 310, in addition to improving the movement of electrons into the organic layers 200 may also protect the organic layers from being damaged during the application of the upper ITO layer 320. The bottom electrode 110 is an anode and is laid on top of or integral with the substrate 100. The substrate 100 may be glass, silicon, or some other support material.

When a potential difference is applied across the device 10, negatively charged electrons move from the cathode layer 320 to the EIL layer 310 and finally into the layer(s) of organic material 200. At the same time positive charges (holes), move from the anode 120 to the hole-injecting layer (if present) and finally into the same organic material 200. When the positive and negative charges combine in the organic material 200, they produce photons, which are transmitted through the EIL layer 310 and the transparent cathode layer 320 to the viewer.

The wave length—and consequently the color—of the photons depends on the material properties of the organic material in which the photons are generated. The color of light emitted from the OLED device can be controlled by the selection of the organic material, or by the selection of dopants (typically fluorescent dye molecules), or by other techniques known in the art. Different colored light may be generated by mixing the emitted light from different OLEDs. For example, white light may be produced by mixing blue, red, and green light simultaneously.

In order for the light generated by the organic layers 200 to be viewed, it must pass through the EIL layer 310 and the cathode layer 320. Accordingly, these top layers should be largely transparent to the wavelength of light generated. For a blue OLED, the light that is to be passed to the viewer has a wavelength range centered approximately on 520 nm. The “transparent” requirement of the top conductive layers in an up-emitting OLED device is typically fulfilled by selecting a very thin lower EIL layer 310 (e.g. MgAg, which is semi-transparent) and an upper cathode layer 320 (e.g. ITO, which is relatively transparent).

The lower EIL layer 310 should not only be conductive and transparent, but also provide sputter protection of the underlying organic layer 200 during the application of the upper ITO layer 320. Left unprotected, the organic layer 200 could be significantly damaged during the process of sputter coating the upper ITO layer 320 onto the device 10.

With continued reference to FIG. 1, a MgAg EIL layer 310 preferably should be in the range of 10 to 20 nm thick so as to be semi-transparent to the light generated by the organic stack 200. For example, an MgAg layer 310 that is approximately 15 nm thick may have a transparency of about 40% (for light at a wavelength of about 520 nm). An MgAg layer 310 of this thickness, however, may not provide sufficient sputter protection of the organic layer 200 so as to enable the manufacture of a high quality OLED device (i.e. an OLED device with uniform emission, low turn-on and drive voltages, high brightness, and high efficiency). Increasing the thickness of the MgAg layer 310 so as to improve sputter protection, however, increases light absorption by this layer and thus reduces the amount of light transmitted from the organic stack 200 to the viewer. Likewise, in OLED devices 10 that utilize an EIL layer 310 comprised of MgAg and/or CuPc, improvements to sputter protection of the organic stack 200 are achieved by increasing the thickness of the MgAg or the CuPc (or both) layers, which correspondingly reduces the transparency of layer 310.

Thus, it would be advantageous to increase the thickness of the lower MgAg layer 310 for processing and sputter protection purposes. However, increasing the thickness of the lower MgAg layer 310 undesirably reduces the overall brightness of the OLED device 10 due to the increased light absorption by the MgAg layer (i.e., a thicker MgAg layer 310 blocks more of the light produced by the organic layer 200). Accordingly, there is a need for an OLED device, and method of making an OLED device, in which improved sputter protection of the organic stack may be achieved without sacrifice of the necessary transparency and electron injection properties of the material selected for sputter protection.

### OBJECTS OF THE INVENTION

It is therefore an object of the present invention to provide improved sputter protection of the organic stack in an OLED.

It is another object of the present invention to provide an OLED electrode with increased transparency.

It is still another object of the present invention to provide an OLED electrode comprising three different layers of conductive material, each having selected levels of conductivity and transparency.

Additional objects and advantages of the invention are set forth, in part, in the description which follows and, in part, will be apparent to one of ordinary skill in the art from the description and/or from the practice of the invention.

### SUMMARY OF THE INVENTION

In response to this challenge, Applicant has developed an innovative top emitting OLED device comprising: a substrate; an anode layer overlying said substrate; a stack of one or more layers of light emitting organic material overlying said anode layer; an EIL overlying said stack of light emitting organic material; a first cathode layer overlying said EIL, said first cathode layer comprising a material selected from the group consisting of a metal, alloy, or intermetallic of: Zr, Au, or Ta; and a second cathode layer overlying said first cathode layer.

Applicant has also developed an OLED device comprising: a substrate; a bottom electrode layer overlying said substrate; a stack of one or more layers of light emitting organic material overlying said bottom electrode layer; a charge injection layer (either an HIL or an EIL) overlying said stack of light emitting organic material; a first top electrode layer overlying said charge injection layer, said first top electrode layer comprising a material having an extinction coefficient k that is at least 50% less than that of the material comprising the first top electrode layer; and a second top electrode layer overlying said first top electrode layer.

Applicant has further developed a bottom emitting OLED device comprising: a substrate; a cathode layer overlying said substrate; a stack of one or more layers of light emitting organic material overlying said cathode layer; a HIL overlying said stack of light emitting organic material; a first anode layer overlying said HIL, said first anode layer comprising a material selected from the group consisting of a metal, alloy, or intermetallic of: Zr, Au, or Ta; and a second anode layer overlying said second anode layer.

Applicant has still further developed a method of making an OLED device comprising the steps of: providing a substrate; forming an anode layer overlying said substrate; forming a stack of one or more layers of light emitting organic material overlying said anode layer; forming an EIL overlying said stack of light emitting organic material; forming a first cathode layer overlying said EIL, said first cathode layer comprising a material selected from the group consisting of a metal, alloy, or intermetallic of: Zr, Au, or Ta; and forming a second cathode layer overlying said first cathode layer.

It is to be understood that both the foregoing general description and the following detailed description are exemplary and explanatory only, and are not restrictive of the invention as claimed. The accompanying drawings, which are incorporated herein by reference, and which constitute a part of this specification, illustrate certain embodiments of the invention and, together with the detailed description, serve to explain the principles of the present invention.

### BRIEF DESCRIPTION OF THE DRAWINGS

FIG. 1 is a cross-sectional view of an up-emitting OLED device of the prior art.

FIG. 2 is a cross-sectional view of an OLED device constructed in accordance with a preferred embodiment of the invention.

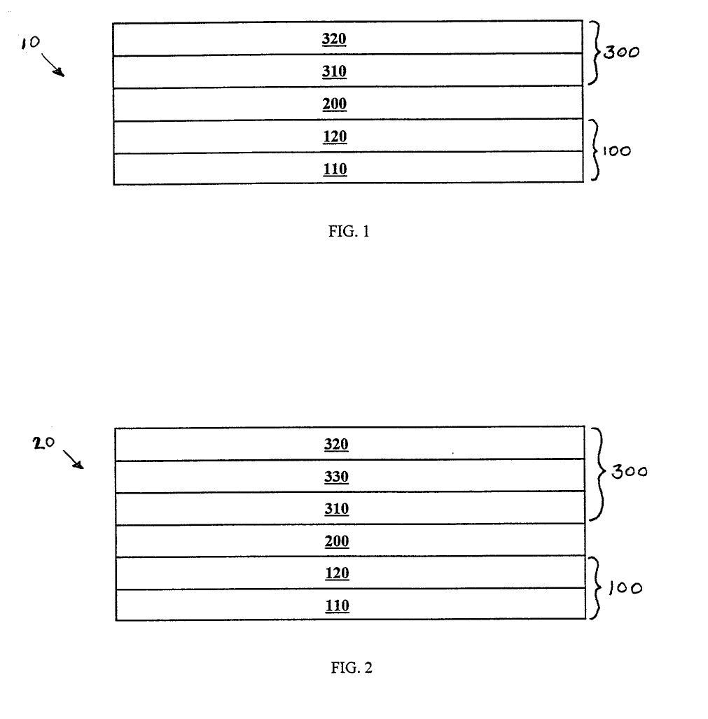

### DETAILED DESCRIPTION OF THE PREFERRED EMBODIMENTS

A preferred embodiment of the invention is shown in FIG. 2. In FIG. 2, an OLED device 20 is constructed as an up-emitting structure in the preferred embodiment of the invention. The up-emitting OLED device 20 includes a substrate 100, a bottom electrode 110, and an optional overlying HIL 120. The substrate 100 is preferably comprised of silicon and may include pixel electrodes and driver circuitry integrated into the silicon material. The anode 110 is preferably Mo or MoOx, but may comprise any other suitable layer or layers of electrically conductive material.

A stack 200 of one or more layers of light emitting organic material overlies the optional HIL 120. It is appreciated that any known organic material that is capable of producing light may be used in the organic stack 200. Process techniques for applying the organic stack are well known in the art, and it is contemplated that the invention may utilize any and all of these techniques.

A top electrode 300 overlies the organic stack 200. In the preferred embodiment of the invention, the top electrode 300 comprises a cathode. The top electrode 300 preferably includes multiple sublayers of material. An EIL 310 directly overlying the organic stack 200 preferably comprises a layer of MgAg applied using an evaporation process. The MgAg EIL 310 is also preferably deposited as an alloy composition with a Mg:Ag ratio of 10:1, with a preferred thickness of between about 1 and about 50 nm, and a more preferred thickness of from about 1 to about 20 nm and an even more preferred thickness of 8 to 12 nm. Although the preferred EIL is a MgAg alloy, it is appreciated that this layer could comprise other elements or alloys which have the desired charge carrier injection properties.

The first cathode layer 330 overlying the EIL layer 310 is a metal, metallic alloy, or intermetallic compound that is conductive. The first cathode layer 330 may comprise a material selected from a metal, metallic alloy, or intermetallic that includes any one or more of the elements Zr, Au, or Ta, which may be applied using an evaporation or sputtering process. The material comprising the first cathode layer 330 is selected such that at the desired emission wavelengths of the OLED device 20, the absorption (or extinction coefficient) of the first cathode layer is less than that of the MgAg alloy, and in particular, is less than that of Mg. Accordingly, the preferred element, metal, alloy, or intermetallic compound comprising the first cathode layer 330 should have an extinction coefficient at least 50% less than that of the EIL 310, and preferably more than 100% less over a majority of the OLED emission spectrum. There are numerous materials that may be used for first cathode layer 330, but zirconium is preferred. The first cathode layer 330 may be between about 1 and about 100 nm thick, but is preferably between about 10 and about 50 nm thick, and more preferably between about 10 and about 30 nm thick.

A second cathode layer 320 overlying the first cathode layer 330 is preferably thicker than about 50 nm, is a highly transparent, and is preferably a highly conductive oxide deposited by any suitable means, but preferably by sputter deposition, and more preferably RF or DC magnetron sputtering. The second cathode layer 320 is more preferably comprised of ITO (indium tin oxide). When the more preferred second cathode ITO layer 320 is deposited using a DC magnetron argon plasma sputtering process, for example, oxygen is typically added to the argon plasma to enhance the sputtering of the ITO layer. However, the argon plasma (and oxygen contained therein) that is used for the ITO sputtering is detrimental to the materials in the organic stack 200. The combination of the EIL layer 310 and the first cathode layer 330 provides protection to the organic stack 200 during the sputtering process of the ITO layer 320 while reducing light transmission losses.

In accordance with the invention the EIL layer 310 and first cathode layer 330 protect the organic stack 200 during the sputtering process. The overall thickness of the layers providing sputter protection is increased from only the thickness of the EIL 310 to the combined thickness of the EIL 310 and the first cathode layer 330 without serious degradation of light transmission out of the device. Proper selection of material for the first cathode layer 330 results in a greater than 1:1 ratio of sputter protection gains to light transmission losses. Without limiting the scope of the invention or being tied down to a particular theory, it is believed that these gains may be attributable to the first cathode layer 330 having a lower energy plasma edge/frequency than the EIL 310. The invention may be particularly beneficial when practiced in connection with blue-emitting (i.e., high optical frequency) OLEDs having an emission spectrum in the range of approximately 400 to 500 nm because the light transmittance of metals in the 400 to 500 nm spectrum varies substantially from metal to metal (i.e., the plasma edges can vary significantly between various metals, alloys and intermetallic compounds in this spectral range).

The first cathode layer 330 should be a good conductor to allow proper conduction through the device.

Without limiting the scope of the invention, it is believed that performance gains exhibited by an OLED device made in accordance with the invention are attributable to the light absorption properties of the material used in the first cathode layer 330. The light absorption characteristic of a metal, alloy, or intermetallic is determined by the absorption coefficient which is, at a given light wavelength or frequency, proportional to the extinction coefficient k. As a rough guideline (because k depends on the method of deposition and morphology of the metal), Table 1 lists the extinction coefficients at different energy levels (green/blue range of the visible spectrum) for a few metals, together with the typical values of electrical resistivity. The information set forth in Table 1 originates from the CRC Handbook of Chemistry and Physics, 78th edition, 1997-98.

TABLE 1

| | Extinction coefficient k | | | | |
|---|---|---|---|---|---|
| | (from CRC Handbook, 78th edition) | | | | Resistivity |
| Metal | At 2.4 eV | At 2.5 eV | At 2.6 eV | At 2.8 eV | (μOcm) |
| Ag | | 3.09 | | | 1.467 |
| Au | 1.86 | 1.59 | 1.54 | 1.77 | 2.051 |
| Cu | 2.6 | | 2.5 | 2.36 | 1.543 |
| Mg | | 2.92 | | | 4.05 |
| Ta | 1.92 | 1.98 | 2.02 | 2.14 | 12.2 |
| Ti | 2.47 | 2.39 | 2.34 | 2.29 | 39 |
| Zr | 0.92 | 0.90 | 0.88 | 0.84 | 38.8 |

Table 1 lists a number of metals with extinction coefficients lower than those of Mg and Ag in the discussed spectral range, with the most outstanding example being zirconium. In addition to Zr, Table 1 shows that there may be other metals, as well as alloys and intermetallic compounds, that also provide low extinction coefficients (i.e., lower than those of Mg and Ag) in the desired spectral range.

Table 1 shows that over the blue/green spectral range, Zr has an extinction coefficient about a factor of three lower than that of Mg and Ag. This means that a layer of Zr may be three times as thick as a layer of Mg or Ag and still provide approximately the same transparency in this spectral range. A layer of Zr three times as thick as a layer of MgAg provides superior sputter protection.

Because k typically increases with increasing wavelength λ in the range of the plasma edge, the k(λ) spectrum of the material comprising the first cathode layer 330 (and that of the EIL, e.g., MgAg), if properly chosen, may also have the added benefit of suppressing the low-energy tail of blue-emitting OLEDs by absorption, i.e., the blue OLED low energy tail emission will be absorbed more strongly than the high energy emission. Thus, the invention may also provide a beneficial color filter function for blue emission OLEDs.

The invention can be applied in the construction of any OLED device structure (i.e. up-emitting and down-emitting) as long as there is a need for at least one transparent (or semitransparent) electrode. With respect to the foregoing description of the invention, it is appreciated that the top electrode 300 may be an anode, rather than a cathode.

It will be apparent to those skilled in the art that various modifications and variations can be made in the construction, configuration, and/or operation of the present invention without departing from the scope or spirit of the invention. For example, in the embodiments mentioned above, minor variations in the thickness and composition of the semitransparent material in the multilayer electrodes may be made without departing from the scope of the invention. The above described structures and process methods can be used on a device having any kind of substrate material, including opaque substrates when making up-emitting OLED devices without departing from the intended scope of the invention. Variations in the shapes, sizes, and patterns of anode, cathode, organic stack, and electron injector layers, may also be made without departing from the scope and spirit of the invention. Further, it may be appropriate to make additional modifications or changes to the process for providing each of the layers in the disclosed devices without departing from the scope of the invention. Thus, it is intended that the present invention cover the modifications and variations of the invention provided they come within the scope of the appended claims and their equivalents.

What is claimed is:

1. A top emitting OLED comprising:
a substrate;
an anode layer overlying said substrate;
a stack of one or more layers of light emitting organic material overlying said anode layer;
a first cathode layer overlying said stack of light emitting organic material;
a second cathode layer overlying said first cathode layer, said second cathode layer comprising a material selected from the group consisting of a metal, alloy, or intermetallic of: Zr, Au, or Ta; and
a third cathode layer overlying said second cathode layer.

2. The OLED device of claim 1 wherein the cathode layer is zirconium.

3. The OLED device of claim 1 wherein the electron injection layer comprises a material selected from the group consisting of: Mg, Ag, MgAg, CuPc, and MgAg CuPc.

4. The OLED device of claim 3 wherein the second cathode layer comprises ITO.

5. The OLED device of claim 4 wherein the substrate comprises silicon.

6. The OLED device of claim 5 wherein the first cathode layer has a thickness of about 1 to about 100 nm.

7. The OLED device of claim 5 wherein the thickness of the first cathode layer is from about 10 to about 50 nm.

8. The OLED device of claim 5 wherein the thickness of the first cathode layer is from about 10 to about 30 nm.

9. The OLED device of claim 1 wherein the second cathode layer comprises ITO.

10. The OLED device of claim 1 wherein the substrate comprises silicon.

11. The OLED device of claim 1 wherein the first cathode layer has a thickness of about 10 to about 30 nm.

12. An OLED device comprising:
a substrate;
a bottom electrode layer overlying said substrate;
a stack of one or more layers of organic material overlying said bottom electrode layer wherein at least one of the layers of organic material is a light emitting layer;
a charge injection layer overlying said stack of light emitting organic material;
a first top electrode layer overlying said charge injection layer, said first top electrode layer comprising a material having an extinction coefficient k that is at least 50% less than that of the material comprising the charge injection layer; and
a second top electrode layer overlying said first top electrode layer.

13. The OLED device of claim 11 wherein the first top electrode layer has a thickness of about 1 to about 100 nm.

14. The OLED device of claim 11 wherein the first top electrode layer has a thickness of about 10 to about 50 nm thick.

15. The OLED device of claim 11 wherein the first top electrode layer has a thickness of about 10 to about 30 nm thick.

16. The OLED device of claim 11 wherein the bottom electrode comprises an anode and the top electrode comprises a cathode.

17. The OLED device of claim 11 wherein the bottom electrode comprises a cathode and the top electrode comprises an anode.

18. The OLED device of claim 1 further comprising a hole injection layer between the anode layer and the stack of one or more layers of light emitting organic material.

19. The OLED device of claim 1 wherein said OLED device is blue-emitting.

20. A bottom emitting OLED device comprising:
a substrate;
a cathode layer overlying said substrate;
a stack of one or more layers of light emitting organic material overlying said cathode layer;
a first anode layer overlying said stack of light emitting organic material;
a second anode layer overlying said first anode layer, said second anode layer comprising a material selected from the group consisting of a metal, alloy, or intermetallic of: Zr, Au, or Ta; and
a third anode layer overlying said second anode layer.

21. A method of making an OLED device comprising the steps of:
providing a substrate;
forming an anode layer overlying said substrate;
forming a stack of one or more layers of light emitting organic material overlying said anode layer;
forming a first cathode layer overlying said stack of light emitting organic material; forming a second cathode layer overlying said first cathode layer, said second cathode layer comprising a material selected from the group consisting of a metal, alloy, or intermetallic of: Zr, Au, or Ta; and
forming a third cathode layer overlying said second cathode layer.
